(19) United States
(12) Patent Application Publication
(10) Pub. No.: US 2011/0042132 A1
(43) Pub. Date: Feb. 24, 2011

(54) METHOD OF PRODUCING AN ELECTRICALLY CONDUCTING VIA IN A SUBSTRATE

(76) Inventor: Leander DITTMANN, Lausanne (CH)

Correspondence Address: Pearl Cohen Zedek Latzer, LLP, 1500 Broadway, 12th Floor, New York, NY, 10036, US

(21) Appl. No.: 12/858,783

(22) Filed: Aug. 18, 2010

Related U.S. Application Data
(60) Provisional application No. 61/235,113, filed on Aug. 19, 2009.

(51) Int. Cl. H05K 1/11; B05D 3/14

(52) U.S. Cl. 174/266; 427/545

(57) ABSTRACT

The present invention relates to a method of producing an electrically conducting via in a substrate and to a substrate produced thereby. In particular, in one embodiment, the present invention relates to a substrate, such as a printed circuit board having one or several metal-free electrically conducting vias.

### CROSS-REFERENCE TO RELATED APPLICATIONS

This application claims the benefit under 35 U.S.C. §119(e) of U.S. Provisional Patent Application No. 61/235,113, filed Aug. 19, 2009, which is incorporated by reference herein in its entirety.

### FIELD OF THE INVENTION

The present invention relates to a method of producing an electrically conducting via in a substrate and to a substrate produced thereby. In particular, in one embodiment, the present invention relates to a substrate, such as a printed circuit board (PCB) having one or several metal-free electrically conducting vias.

### BACKGROUND OF THE INVENTION

Printed circuit boards (PCBs) are used to support and electrically connect electronic components using conductive pathways etched from metal sheets, such as copper sheets which have been laminated onto a non-conductive substrate. Sometimes it is necessary to establish through-contacts through these circuit boards in order to establish electrical contacts from one side of the board to the other. Historically, this has been achieved in the past by embedding metal bolts or pins into the board. However, this approach is limited in terms of its resolution. Alternatively, through-holes can be drilled using tungsten carbide drills, and the holes thus established are subsequently electroplated. The smallest size that can thus be achieved in terms of hole diameter is approximately 200 um. The smaller the diameter of the holes created, the more likely the respective drill is to break and to wear. Accordingly, for holes having a diameter <200 um, lasers have been used for ejecting material from the substrate. Subsequently, again, the inside of the hole is electroplated.

However, also this technique is error-prone, and, especially for small laser-created holes, the process of electroplating is difficult to achieve for such small diameter holes because it requires the deposition of an initial germination layer which allows a subsequent metallization.

Accordingly, there is a need in the art for alternative methods of producing substrates having electrically conducting through-vias, especially on a small scale. Accordingly, an object of the present invention was to provide for an alternative method that allows the production of electrically conducting through-vias in electrically insulating substrates, such as printed circuit boards. It was also an object of the present invention to provide for a method that is easy to perform and does not require metallization steps, but produces such through holes in one working procedure.

### SUMMARY OF THE INVENTION

The objects of the present invention are solved by a method of producing an electrically conducting via in a substrate made of an electrically insulating material, said method comprising the steps:
a) providing a substrate made of at least one electrically insulating material,
b) placing said substrate between two electrodes, said two electrodes being connected to a user-controlled and, optionally, process-controlled voltage source,
c) applying a voltage to said substrate,
d) causing a dielectric breakdown and energy dissipation between said two electrodes through said substrate by locally or globally increasing the electrical conductivity of said substrate by
   applying heat to said substrate at a position of said substrate where said energy dissipation is to occur,
   applying a distortion to said substrate at a position where said energy dissipation is to occur, and/or
   increasing the humidity of the substrate at a position where said energy dissipation is to occur, wherein, in step d) at said position, a modification of said at least one electrically insulating material into an electrically conducting material occurs, wherein said modification is due to
   a chemical transformation of said at least one electrically insulating material, e.g., a pyrolysis, oxidation or carbonization,
   or a doping of said at least one electrically insulating material by component(s) of the atmosphere in which step d) takes place or by component(s) of the electrodes,
   thereby generating an electrically conducting via.

Upon energy dissipation the substrate material is locally modified into an electrically conducting state. In one embodiment the substrate material is transformed into another material which is electrically conducting by, e.g., pyrolysis or carbonization or by a chemical reaction of part of the substrate material with the surrounding atmosphere. In another embodiment the substrate becomes conducting by, e.g., doping initiated by the energy dissipation, the dopants can be provided by the electrodes or by an atmosphere surrounding the substrate and electrodes. The atmosphere can be a composition of gases (e.g., argon, oxygen, nitrogen, SF6) or liquids (e.g., H₂O, aqueous solutions) adapted to the substrate material. Substrate material may be not or partly ejected during the process.

In one embodiment said electrically conducting via is a through-hole or blind hole, the wall of which has been made electrically conducting in step d), wherein said through-hole extends from one side of the substrate to another side of the substrate, and wherein said through-hole results from the ejection of material from said substrate, upon energy dissipation in step d).

In another embodiment, said electrically conducting via is a body of electrically conducting material extending from one side of the substrate to another side of the substrate, without a hole or channel having been formed in step d), said electrically conducting material having been generated from said at least one electrically insulating material during said energy dissipation in step d).

In one embodiment said at least one electrically insulating material is a carbon-containing polymer, which, during step d), is carbonized at said position where said energy dissipation occurs, and is thus made electrically conducting and, in the case of a through-hole, partially ejected from said substrate.

In one embodiment said carbon-containing polymer is a thermosetting plastic or polytetrafluoroethylene.

In one embodiment said thermosetting plastic is selected from epoxy resins, polyimides, melamine resins, phenol-formaldehyde resins, urea-formaldehyde foams, and thermosetting polyesters.

In one embodiment said at least one electrically insulating material is reinforced by an electrically insulating filler material, such as paper, cotton paper, glass fibers, woven glass, and cellulose fibers.

In one embodiment in said substrate, said at least one electrically insulating material is arranged in a sheet having two opposing surfaces, and said substrate additionally comprises a layer of electrically conducting material, such as a metal layer, or a layer of semiconducting material attached to one or both opposing surfaces of said sheet of electrically insulating material and covering said one or both opposing surfaces in parts or entirely.

In one embodiment said layer of electrically conducting material is a metal layer, preferably selected from copper layers, silver layers, gold layers, aluminum layers, tin layers, nickel layers, and layers of alloys of any of the foregoing.

In one embodiment after performance of step d), said electrically conducting via is electrically connected to said layer of electrically conducting material by being adjacent to and directly contacting said layer of electrically conducting material.

In one embodiment said substrate is made of an epoxy-resin or a composite epoxy-resin, such as a glass-fiber enforced epoxy-resin.

In one embodiment said substrate is a printed circuit board or a printed circuit board workpiece.

In one embodiment said electrically conducting via resulting from step d) is metal-free.

In one embodiment applying heat to said substrate occurs by means of a laser, and wherein applying a distortion to said substrate occurs by bringing said electrodes which are located on opposite sides of said substrate into contact with said substrate and, optionally, pressing said electrodes onto said substrate, and wherein increasing the humidity of the substrate occurs by exposing said substrate to a water-containing atmosphere.

In one embodiment said voltage applied in step c) is in the range of from 100 V to 20000 V.

In one embodiment said voltage source is connected to one of said electrodes via a serial resistor, said resistor having a resistance of 1 Ohm to 1 MOhm.

In one embodiment said voltage source has a capacitor having a capacitance in the range of from 0-50 nF.

In one embodiment, said voltage is applied over a period in the range of from 1 ms to 5000 ms.

In one embodiment said laser has a power in the range of from 0.5 W to 50 W.

In one embodiment said laser is applied over a period in the range of from 1 ms to 5000 ms, preferably in a focus having a diameter of 1 um to 500 um.

In one embodiment said electrically conducting via has an electrical conductance <1 kOhm.

In one embodiment said electrically conducting via has a diameter in the range of from 0.1 um to 500 um.

The objects of the present invention are also solved by a substrate produced by the method according to the present invention, in particular a printed circuit board having one or several electrically conducting through-holes produced by the method according to the present invention.

### BRIEF DESCRIPTION OF THE DRAWINGS

Embodiments of the invention will be understood and appreciated more fully from the following detailed description in conjunction with the figures, which are not to scale, in which like reference numerals indicate corresponding, analogous or similar elements, and in which:

FIG. 1(A) shows a first embodiment for formation of electrically conducting vias in electrically insulating substrate material.

FIG. 1 (B) shows a second embodiment for formation of electrically conducting vias in electrically insulating substrate material.

FIG. 1(C) shows a third embodiment for formation of electrically conducting vias in electrically insulating substrate material.

FIGS. 2-9a show images of various vias generated using the method in accordance with the present invention.

FIGS. 9b and 9c show conductivity plotted versus distance from the center of the via shown in FIG. 9a.

### DETAILED DESCRIPTION OF THE INVENTION

An “electrically conducting via” as used herein, may either be a through-hole extending from one side to the other side of an electrically insulating substrate, wherein the through-hole has a lining or walls which are electrically conducting and thus allow the establishment of an electrical contact from one side of the substrate to the other. Alternatively, an “electrically conducting via”, as used herein, may also refer to a region within a substrate extending from one surface to an opposite surface of the substrate in which region there is no through-hole and the volume of which is occupied by solid material. This region may for example be a cylindrical body of material extending from one surface to an opposite surface of the substrate. Due to the fact that, in such region, the material is electrically conducting, the region itself is electrically conducting and this allows the establishment of an electrical contact from one side of the substrate to the other.

The inventors have surprisingly found that, when using a substrate made of a least one electrically insulating material, and applying a voltage to said substrate with subsequent energy dissipation through said substrate, it is possible to generate an electrically conducting via, the bulk material of which or the walls of which have been made electrically conducting by the energy dissipation process. In this process, a modification of said at least one electrically insulating material into an electrically conducting material occurs at the position where said energy dissipation occurs and thus where said electrically conducting via is produced. Such modification is due to
a chemical transformation of said at least one electrically insulating material,
or a doping of said at least one electrically insulating material by component(s) of the atmosphere in which step d) takes place or by component(s) of the electrodes.

In this process, in the case of through-holes, material is ejected from the substrate, thus leading to the generation of a hole. In other embodiments, energy dissipation occurs but is controlled in such a manner that no material is ejected from the substrate, whereas, still, a conversion of the originally electrically insulating substrate material into electrically conducting material occurs. This will generate a cylinder or, more generally, body of electrically conducting material extending from one surface of the substrate to the other surface of the substrate, which body of material also allows the establishment of an electrical contact between the two sides of a substrate.

Typically, a voltage is applied to the substrate, and energy dissipation through the substrate is initiated by applying heat by means of a laser or by applying a distortion to the substrate, for example by pressing the two electrodes to the substrate. A device for performing such a dielectric breakdown has been described in WO 2009/059786 filed on Nov. 7, 2008. A “through-hole”, as used herein, is used synonymously with “through-via” and is meant to refer to a hole which extends from one side of the substrate to another side of the substrate. The energy dissipation may lead to an ejection of material, in which such a through-hole is generated. The depth and diameter of the through-hole can be controlled by the voltage, currency, power and voltage supply parameters. The substrate material may already have some conducting traces or an electrically conducting layer, such as a metal foil, e.g., a copper foil attached thereto. If the method according to the present invention is applied to such a substrate, the present inventors have found that these conducting layers are automatically connected with the electrically conducting vias. The substrate may also have only patches of metal, such as patches of copper, silver, gold, tin or metal alloys, attached thereto. If the method according to the present invention is applied to such a substrate at the site(s) of such patches, the present invention have found that these patches are automatically connected with the electrically conducting vias.

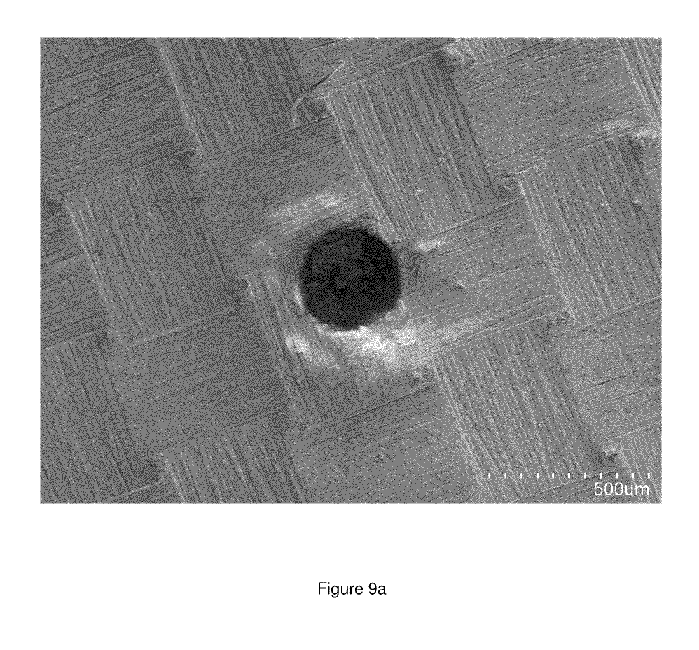

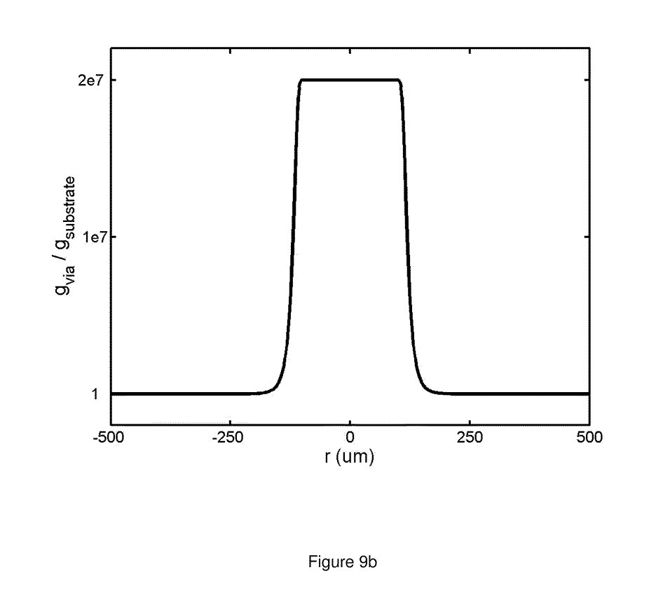

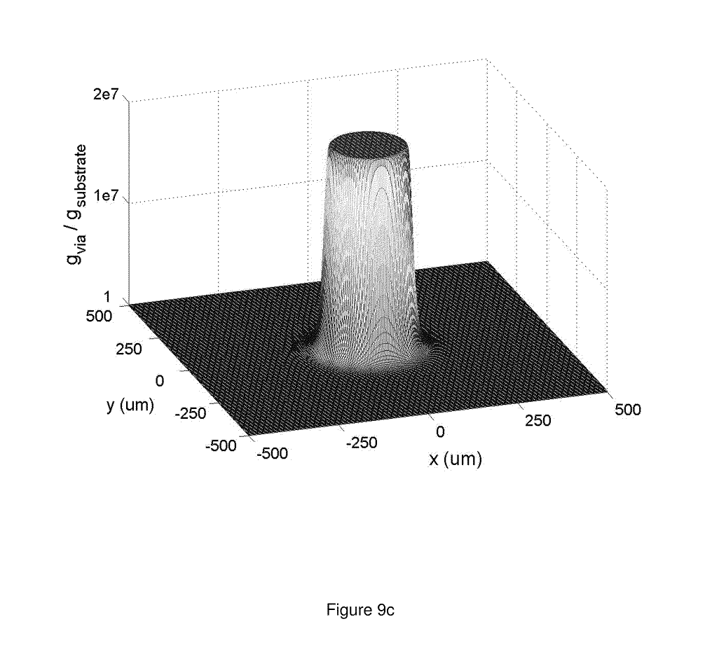

Without wishing to be bound by any theory, the present inventors believe that the process of energy dissipation in accordance with the present invention, when applied to an electrically insulating substrate that is preferably made of a polymeric material, especially of a carbon-containing material, will lead to a partial burning and, in the case of carbon-containing polymers, a carbonization of such material. This, in turn, will lead to an increase in electrical conductivity in those parts where carbonization has occurred. This is shown in FIGS. 9a)-c), wherein an electrically conducting via generated in accordance with the present invention is shown, as well as the corresponding conductivity curve of this via. In preferred embodiments, the at least one electrically insulating material is a thermosetting plastic or polyetrafluorethylene. With these materials it is easier to perform a chemical transformation since these materials, when exposed to high temperatures, do not melt but react chemically by, e.g., burning.

When voltage is applied to the substrate, the process can for example be initiated by applying heat through a laser, or by applying mechanical energy to the substrate, e.g., pressing the two electrodes onto the substrate and thereby locally distorting/deforming it, thus establishing a preferred dissipation path.

If the substrate already has an electrically conducting layer, such as a metal layer/foil or a semiconducting layer attached, as may be the case in a printed circuit board, the wavelength of the laser has to be adapted such that it is only absorbed by the substrate, whereas the metal layer or semiconducting layer attached to the substrate is transparent for such laser. Alternatively or additionally, the laser preferably is incident on the side of the substrate having no metal layer or semiconducting layer attached.

A plurality of through-holes in a substrate can be generated by having a temporary insulating layer attached to the substrate, which insulating layer may be solid, liquid or gaseous and serves the purpose of shielding a through-hole once created so as to avoid short circuiting of the substrate through holes already created. The concept thereof is described in U.S. Provisional Patent Application No. 61/119,255, filed on Dec. 2, 2008.

The method in accordance with the present invention can also be combined with traditional methods of via generation, such as drilling by tungsten carbide.

A device for performing the method in accordance with the present invention has already been described in International Patent Application Publication No. WO 2009/059786, filed on Nov. 7, 2008 and published May 14, 2009.

The diameters of the electrically conducting vias/through-holes/blind holes achieved are in the range of from 0.1 um to 500 um, and their electrical conductivity is <1 kOhm. Typical ranges of voltages that are applied are in the range of from 100 V to 20000 V. The voltage source has a serial resistor, having a resistance in the range of from 1 Ohm to 1 MOhm. Additionally, there may be a capacitor having a capacitance in the range of from 0-50 nF.

If a laser is used, the laser power typically is in the range of 0.5 W to 50 W. A typical example is a CO₂-laser. Both voltage and laser/heat are applied for a time period in the range of from 1 ms to 5000 ms.

It should be noted that in the method according to the present invention, the steps of voltage application and heat application may occur concomitantly, i.e. at the same time or in an overlapping manner. For example one may first apply the voltage and subsequently apply heat, while the voltage is still applied, or one may first apply heat and subsequently voltage, whilst continuing the heat application. The present invention allows the formation of electrically conducting vias through otherwise electrically insulating substrate at a resolution which has so far not been achieved. Moreover the method in accordance with the present invention is easy to perform.

Moreover, reference is made to the enclosed figures, wherein the following is shown:

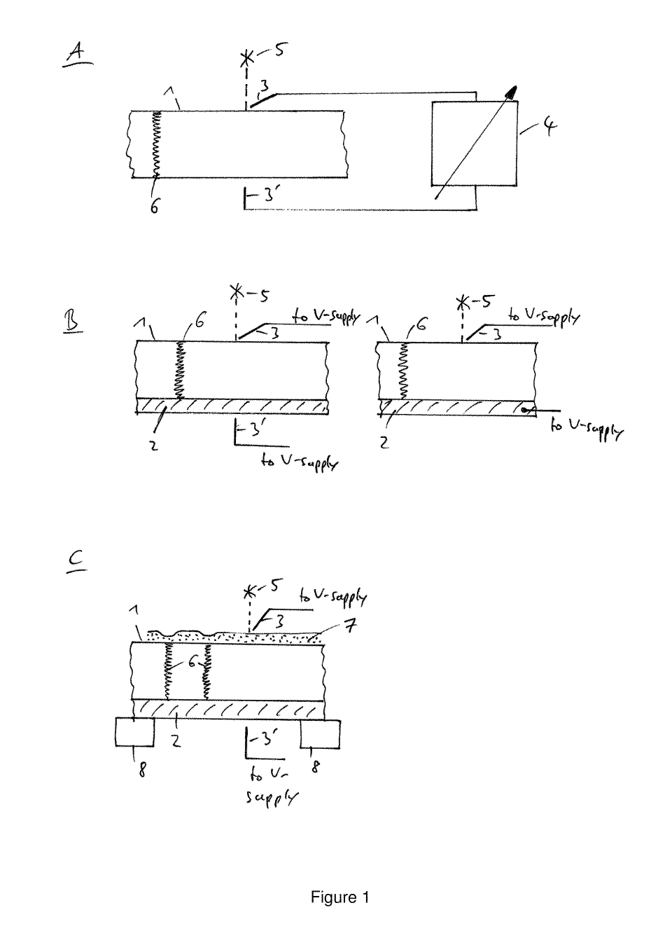

FIG. 1(A) shows a scheme of an embodiment for formation of electrically conducting vias (6) in electrically insulating substrate material (1) (e.g., epoxy or glass-fiber enforced epoxy). The substrate is placed between two electrodes (3, 3′) connected to a user and optionally process controlled voltage source (4). Upon application of a voltage between the electrodes and lowering the break-down voltage of the substrate dissipation inside the substrate is triggered. Lowering of break-down voltage is achieved by introducing heat (e.g., by means of laser irradiation (5)) or by introducing a distortion (e.g., by touching/pressing the electrodes against the substrate thus establishing a preferred discharge path. Duration of energy dissipation and properties of voltage source determine extension of the region where energy was dissipated. Energy dissipation leads to a change of substrate properties within this region, in particular to a transformation to an electrically conducting state (e.g., by carbonization). Width of conducting area/channel can be controlled by e.g., duration, voltage, current. This area/channel can also be a hole with an electrically conducting inner surface, when material was partly removed during the process.

FIG. 1 (B) shows a scheme of an embodiment wherein the substrate material may have an electrically conducting or semiconducting layer (2) (e.g., metal foil, deposited III-V-semiconductor) on one or both surfaces. Instead of using an electrode the electrically conducting layer may also directly be clamped to the electrode/voltage supply. The created via (6) extends through the substrate material (1) to the layer (2) establishing an electrical contact between the via (6) and the layer (2). The layer (2) is not altered in its properties. If a laser (5) is used to trigger the process by irradiation through the layer (2) its wavelength must be chosen such that it is sufficiently transmitted by the layer and absorbed by the substrate.

FIG. 1(C) shows the formation of multiple vias in close proximity on a single substrate by means of a shielding layer (7). The shielding layer may be solid (e.g., wax) or liquid (e.g., oil) or a gas (e.g., SF6). To initiate energy dissipation in the substrate, the shielding layer has to be removed or to be raised in conductivity. This can be done by e.g., heating by e.g., using a laser. After formation of via (6) in the substrate, the via is covered by (7) again. If the shielding layer (7) is a liquid or a gas, this may happen spontaneously, if it is a solid, the reflux can be induced by application of heat. The substrate attached to a moveable support (8) is moved, voltage is applied to the electrodes and the dissipation process restarts anew using a focused laser beam. Shielding of the pre-existing vias is—depending on the inter-via distance and voltage magnitude—required to prevent pre-discharges through the already existing vias.

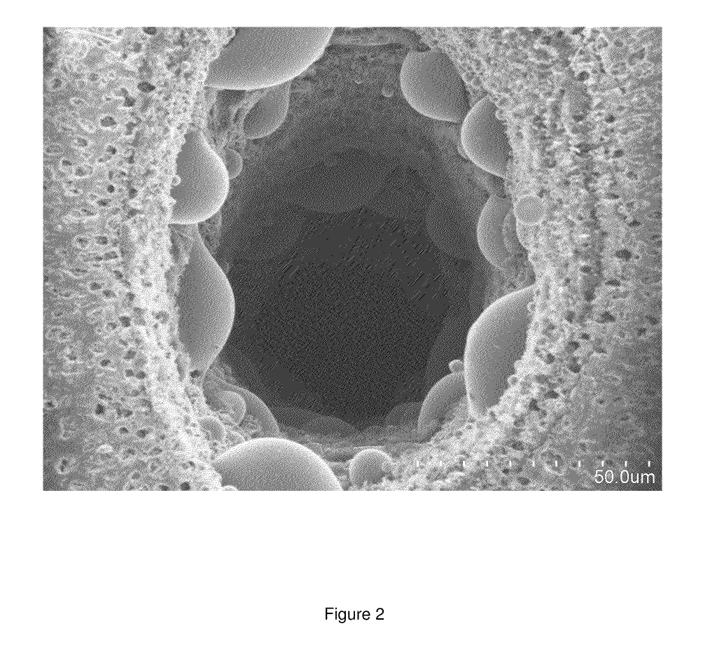

In the following FIGS. 2-9, in the experimental setup, the serial resistor always had a resistance of R=100 Ohm The substrate material was epoxy, glass-fiber reinforced, with the substrate having a thickness of approximately 0.4 mm. The copper foil had a thickness of <0.1 mm. However, it should be noted that other substrate materials which are typically used in the fabrication of printed circuit boards (PCB) can be used as well. Examples are polytetrafluoroethylene, synthetic resin bonded paper, such as phenolic cotton paper, and polyester.

FIGS. 2-9 show various vias generated using the method in accordance with the present invention. Moreover, and more specifically, the following parameters were used (C=capacitance of voltage source; U=applied voltage):

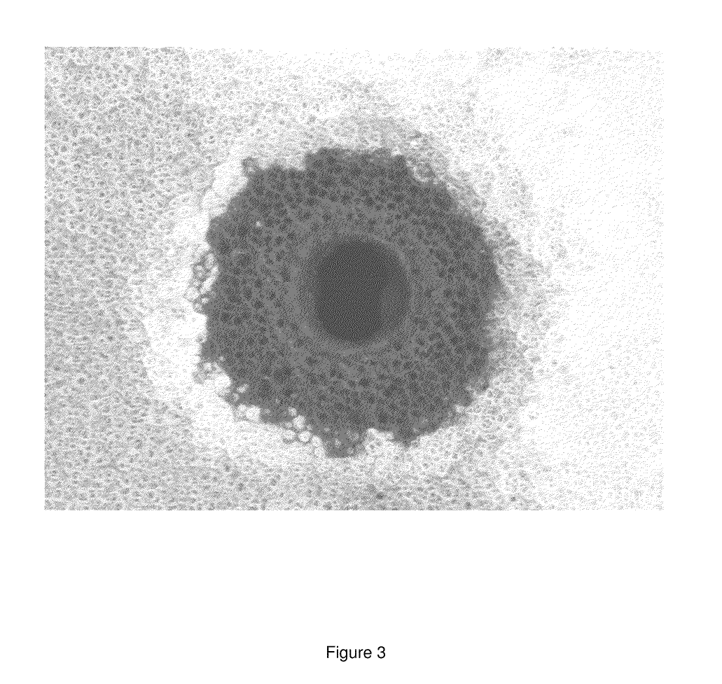

FIGS. 2 and 3: C=3.5 nF, U=5 kV, applied for 100 ms, CO₂-laser power=2 W, applied for 100 ms. FIG. 2 shows the side of the substrate where the laser was applied (focus approximately 100 um), FIG. 3 shows the opposite side.

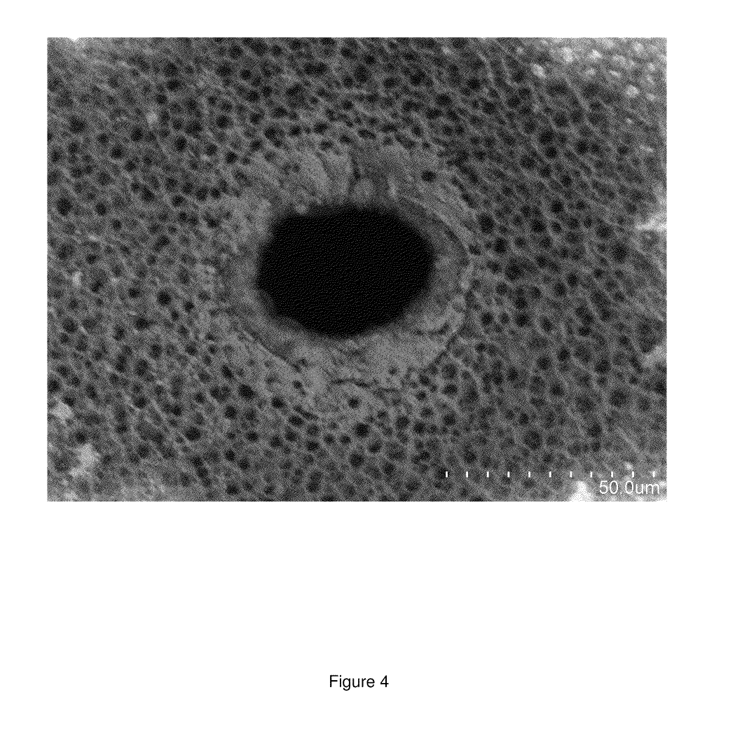

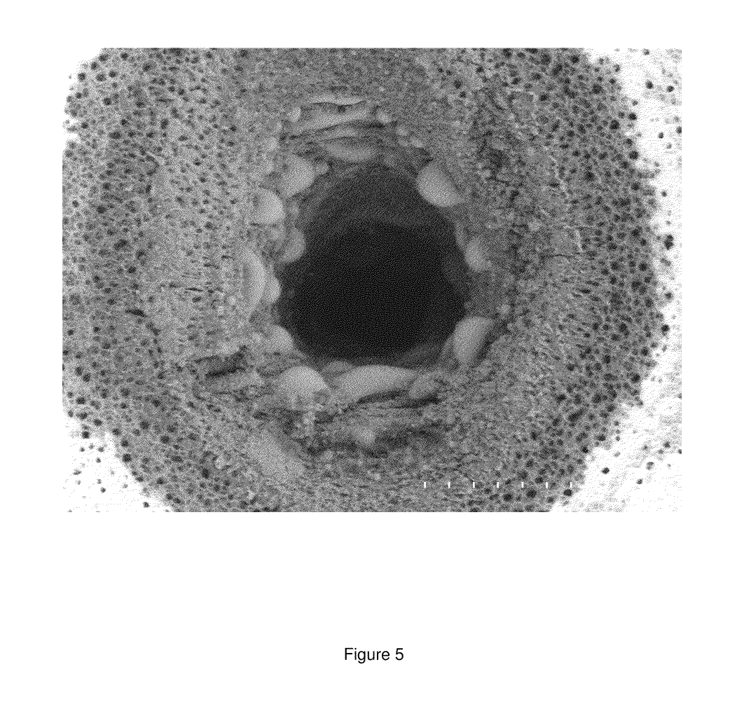

FIG. 4 (non-laser side) and FIG. 5 (laser side):

C=5.6 nF, U=8 kV applied for 100 ms, CO₂-laser power=2.5 W applied for 50 ms (focus approximately 100 um).

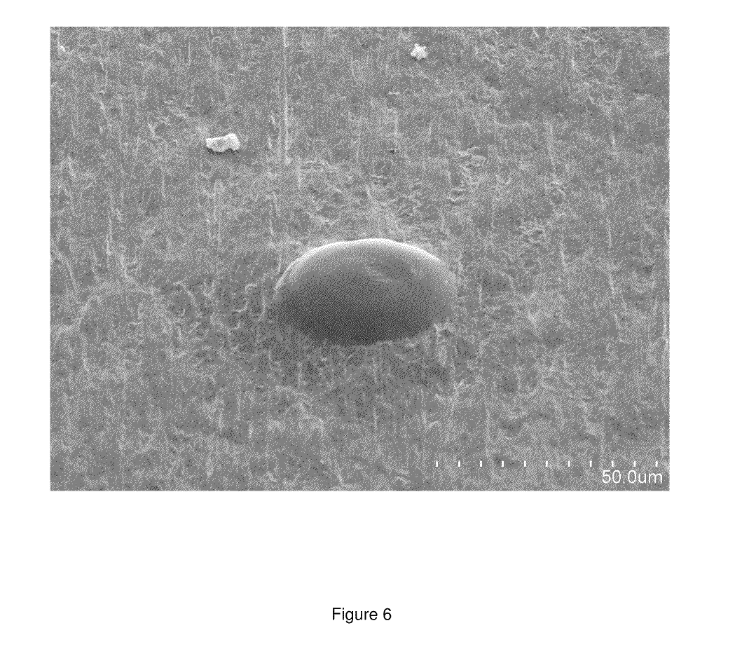

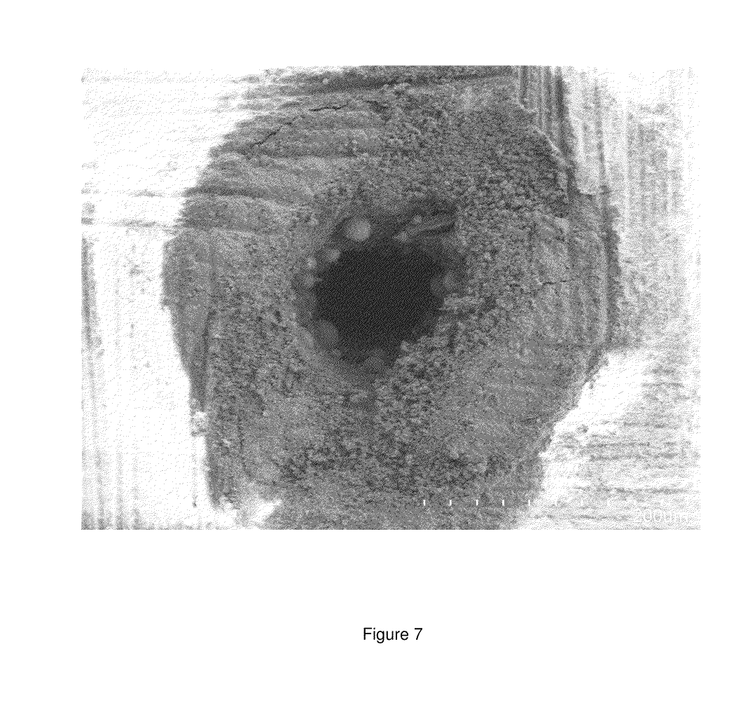

FIGS. 6 and 7 show the result that can be achieved if on one side of the electrically insulating substrate an electrically conducting material, in this case a metal foil, more specifically a copper foil <0.1 mm thick, has been attached. FIG. 6 shows the side where the metal foil is attached. The following parameters were used R=100 Ohm, C=5.6 nF, U=6 kV, applied for 200 ms, the CO₂-laser power was 5 W for 50 ms (focus approximately 100 um). The laser was applied to the side of the substrate where no metal was present such that no reflection of the laser at the metal foil occurred. FIG. 6 shows that the copper is somewhat deformed but no hole is generated. FIG. 7 shows the other side of the same substrate, where clearly a hole has been generated.

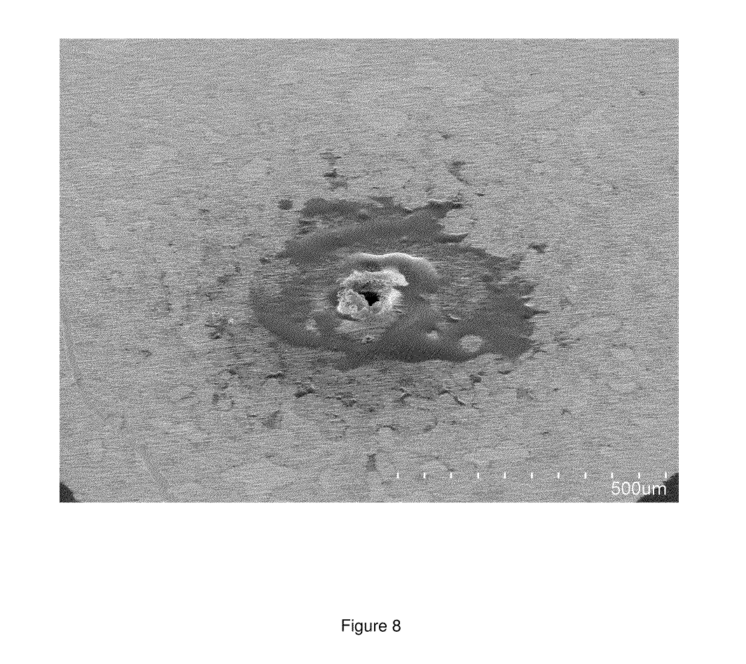

FIG. 8 shows a similar treatment of a substrate onto which a metal foil (copper foil as in FIGS. 6 and 7) has been attached. This time, however, in addition thereto, an insulating black tape has been attached to the metal foil which also enables a perforation of the metal/copper foil itself. The hole in the metal foil is generated by the extremely sudden ejection of material from the substrate. The parameters are for this example: C=5.6 nF, U=6 kV applied for 400 ms, CO₂-power 5 W applied for 250 ms (focus approximately 100 um).

FIG. 9 shows a via generated in accordance with the present invention in glass-fiber enforced epoxy-substrate wherein no through-hole was formed. Panel a) shows a photography of this via which via has a diameter of approximately 300 um. On the back of the substrate there is a copper foil (not shown in the photography). The parameters used for generating this via are C=3.5 nF, U=4 kV applied for 130 ms, CO₂-laser power=2 W, applied for 60 ms. Panels b) and c) show the conductivity plotted versus distance from the center of the via (in um). The y-values are the ratio of the electrical conductivity within the via (“gᵥᵢₐ”) normalized by the conductivity of the substrate outside the via (“g_{substrate}”). In this case, g_{substrate} is <1/(2 GOhm). The measured resistance in the substrate was >2 GOhm, thus corresponding to g_{substrate} being <1/(2 GOhm). The measured resistance in the via was 100 Ohm, thus corresponding to gᵥᵢₐ being 1/(100Ω). For calculating purposes, for the resistance in the substrate 2 GOhm were used, and the ratio of the electrical conductivities is thus at least 2×10⁷. Panels b) and c) show a 2-dimensional and 3-dimensional representation of this ratio plotted versus distance from the center of the via (which is at 0 um). These results show that electrically conducting vias can be generated in a very precise manner using the method in accordance with the present invention.

The features of the present invention disclosed in the specification, the claims and/or in the accompanying drawings, may, both separately, and in any combination thereof, be material for realizing the invention in various forms thereof.

1. A method of producing an electrically conducting via in a substrate made of an electrically insulating material, said method comprising the steps:
a) providing a substrate made of at least one electrically insulating material,
b) placing said substrate between two electrodes, said two electrodes being connected to a user-controlled and, optionally, process-controlled voltage source,
c) applying a voltage to said substrate,
d) causing a dielectric breakdown and energy dissipation between said two electrodes through said substrate by locally or globally increasing the electrical conductivity of said substrate by
applying heat to said substrate at a position of said substrate where said energy dissipation is to occur,
applying a distortion to said substrate at a position where said energy dissipation is to occur, and/or
increasing the humidity of the substrate at a position where said energy dissipation is to occur,
wherein, in step d) at said position, a modification of said at least one electrically insulating material into an electrically conducting material occurs, wherein said modification is due to
a chemical transformation of said at least one electrically insulating material, wherein said chemical transformation is pyrolysis, oxidation or carbonization, or
a doping of said at least one electrically insulating material by one or more components of the atmosphere in which step d) takes place or by one or more components of the electrodes,
thereby generating an electrically conducting via.

2. The method according to claim 1, wherein said electrically conducting via is a through-hole or blind hole, the wall of which has been made electrically conducting in step d), wherein said through-hole extends from one side of the substrate to another side of the substrate, and wherein said through-hole results from the ejection of material from said substrate, upon energy dissipation in step d).

3. The method according to claim 1, wherein said electrically conducting via is a body of electrically conducting material extending from one side of the substrate to another side of the substrate, without a hole or channel having been formed in step d), said electrically conducting material having been generated from said at least one electrically insulating material during said energy dissipation in step d).

4. The method according to claim 1, wherein said at least one electrically insulating material is a carbon-containing polymer, which, during step d), is carbonized at said position where said energy dissipation occurs, and is thus made electrically conducting and, in the case of a through-hole, partially ejected from said substrate.

5. The method according to claim 4, wherein said carbon-containing polymer is a thermosetting plastic or polytetrafluoroethylene.

6. The method according to claim 5, wherein said thermosetting plastic is selected from epoxy resins, polyimides, melamine resins, phenol-formaldehyde resins, urea-formaldehyde foams, and thermosetting polyesters.

7. The method according to claim 1, wherein said at least one electrically insulating material is reinforced by an electrically insulating filler material, such as paper, cotton paper, glass fibers, woven glass, and cellulose fibers.

8. The method according to claim 1, wherein in said substrate, said at least one electrically insulating material is arranged in a sheet having two opposing surfaces, and wherein said substrate additionally comprises a layer of electrically conducting material, such as a metal layer, or a layer of semiconducting material attached to one or both opposing surfaces of said sheet of electrically insulating material and covering said one or both opposing surfaces in parts or entirely.

9. The method according to claim 8, wherein said layer of electrically conducting material is a metal layer, preferably selected from copper layers, silver layers, gold layers, aluminum layers, tin layers, nickel layers, and layers of alloys of any of the foregoing.

10. The method according to claim 8, wherein, after performance of step d), said electrically conducting via is electrically connected to said layer of electrically conducting material by being adjacent to and directly contacting said layer of electrically conducting material.

11. The method according to claim 1, wherein said substrate is made of an epoxy-resin or a composite epoxy-resin, such as a glass-fiber enforced epoxy-resin.

12. The method according to claim 1, wherein said substrate is a printed circuit board or a printed circuit board workpiece.

13. The method according to claim 1, wherein said electrically conducting via resulting from step d) is metal-free.

14. The method according to claim 1, wherein applying heat to said substrate occurs by means of a laser, and wherein applying a distortion to said substrate occurs by bringing said electrodes which are located on opposite sides of said substrate into contact with said substrate and, optionally, pressing said electrodes onto said substrate, and wherein increasing the humidity of the substrate occurs by exposing said substrate to a water-containing atmosphere.

15. The method according to claim 1, wherein said voltage applied in step c) is in the range of from 100 V to 20000 V.

16. The method according to claim 15, wherein said voltage source is connected to one of said electrodes via a serial resistor, said resistor having a resistance of 1 Ohm to 1 MOhm.

17. The method according to claim 1, wherein said voltage source has a capacitor having a capacitance in the range of from 0-50 nF.

18. The method according to claim 1, wherein said voltage is applied over a period in the range of from 1 ms to 5000 ms.

19. The method according to claim 14, wherein said laser has a power in the range of from 0.5 W to 50 W.

20. The method according to claim 14, wherein said laser is applied over a period in the range of from 1 ms to 5000 ms, preferably in a focus having a diameter of 1 um to 500 um.

21. The method according to claim 20, wherein said laser is applied in a focus having a diameter of 1 um to 500 um.

22. The method according to claim 1, wherein said electrically conducting via has an electrical conductance <1 kOhm.

23. The method according to claim 1, wherein said electrically conducting via has a diameter in the range of from 0.1 um to 500 um.

24. A substrate produced by the method according to claim 1, comprising a printed circuit board having one or several electrically conducting through-holes produced by the method according to claim 1.
